(19) United States
(12) Patent Application Publication
(10) Pub. No.: US 2017/0057654 A1
(43) Pub. Date: Mar. 2, 2017

(54) Thermopile Generator for Airplanes and Other Applications

(71) Applicant: Mohamed Ahmed Abdelhalim Elnahhas, Kuwait (KW)

(72) Inventor: Mohamed Ahmed Abdelhalim Elnahhas, Kuwait (KW)

(21) Appl. No.: 15/256,201

(22) Filed: Sep. 2, 2016

Related U.S. Application Data
(60) Provisional application No. 62/213,282, filed on Sep. 2, 2015.

(51) Int. Cl. B64D 41/00; H01L 35/30; H01L 35/32

(52) U.S. Cl. CPC B64D 41/00; H01L 35/32; H01L 35/30

(57) ABSTRACT

An airframe having an integrated thermoelectric generator and a method thereof for providing electricity in an aircraft. A plurality of thermocouple wires is disposed about an aircraft frame to form a thermopile circuit in which electrical current is generated as a result of a temperature difference observed at a cruising altitude. The temperature difference is created by a hot side, interior to the aircraft frame, and a cold side, exterior to the aircraft frame. The thermopile circuit is formed by a first thermoelectric material and a second thermoelectric material that are selected to produce a desired voltage when exposed to the temperature difference. The electric current is harnessed by a transfer cable and directed to an aircraft electrical system to provide power to the desired devices.

The current application claims a priority to the U.S. Provisional Patent application Ser. No. 62/213,282 filed on Sep. 2, 2015.

### FIELD OF THE INVENTION

The present invention relates generally to power generation. More specifically, the present invention provides an airframe having an integrated thermoelectric generator that exploits the Seebeck effect to generate electrical current from a temperature difference observed at a cruising altitude.

### BACKGROUND OF THE INVENTION

For most domestic airplanes, there are two jet engines, one on the port side and the other on the starboard side, each of which are equipped with a generator. Furthermore, one or more additional generators are generally located towards the back of the plane. The generators are used to produce electricity on the plane, so passengers can charge their phones, turn on lights, and so forth, in addition to the essential electrical load required for other control systems. In case of an emergency, turbines will produce electrical power created by wind flow. Except for the wind turbine generator (which is being used in case of emergencies only), all other generators burn fuel to generate the required energy. Both the generators and the fuel provide extra weight to the aircraft reducing the load capacity of the plane and/or the range of flight. Ideally, a lightweight system would be provided in order to generate electricity for the aircraft while minimizing the impact on load capacity and range of flight.

Therefore it is an objective of the present invention to produce electrical energy from the natural phenomenon known as the Seebeck effect, wherein the difference in temperature between the inside and outside of the fuselage, while at cruising altitude, is utilized to generate electricity. Such a system eliminates some or all of the gas generators typically used and the accompanying fuel, hence increasing economic efficiencies of the aircraft. The present invention introduces an airframe having an integrated thermoelectric generator that is able to generate electric current due to the permanent temperature difference between the outside of the airframe and the inside of the airframe while at cruising altitude. In general, the outside of the airframe will be approximately −45° C., while the inside will be about 20° C., providing a sufficient temperature difference to generate electricity.

### BRIEF DESCRIPTION OF THE DRAWINGS

FIG. 1 is a diagram depicting the plurality of thermocouple wires being disposed about the aircraft frame to form the thermopile circuit.

FIG. 2 is a diagram depicting the thermopile circuit, wherein the plurality of thermocouples is arranged in parallel.

FIG. 3 is a diagram depicting the thermopile circuit, wherein the plurality of thermocouples is arranged in series.

FIG. 4 is a diagram wherein the plurality of cold exposed wires is composed of the first thermoelectric material and positioned adjacent the cold side, and wherein the plurality of heat exposed wires is composed of the second thermoelectric material and positioned adjacent the hot side.

FIG. 5 is a diagram wherein the plurality of thermocouple sires is composed of the first thermoelectric material and the girder is composed of the second thermoelectric material; the plurality of thermocouple wires being disposed about the cold side.

FIG. 6 is a diagram wherein the plurality of thermocouple sires is composed of the first thermoelectric material and the girder is composed of the second thermoelectric material; the plurality of thermocouple wires being disposed about the hot side.

FIG. 7 is a flowchart depicting steps for providing electricity in an aircraft using an aircraft frame having an integrated thermoelectric generator.

### DETAIL DESCRIPTIONS OF THE INVENTION

All illustrations of the drawings are for the purpose of describing selected versions of the present invention and are not intended to limit the scope of the present invention.

The present invention provides a thermopile generator for airplanes; more specifically, an airframe having an integrated thermoelectric generator. Furthermore, a method for providing electricity in an aircraft is disclosed. Utilizing the permanent temperature difference between an interior of the aircraft and an exterior of the aircraft while at a cruising altitude, electricity is generated by the thermoelectric generator. The process of generating electricity exploits the Seebeck effect, wherein an electrical current is generated as a result of the observed temperature difference between two dissimilar electrical conductors or semiconductors.

Before explaining at least one embodiment of the present invention in detail, it is to be understood that the thermoelectric generator is not limited in its application to the details of the components and arrangements as described or illustrated. The invention is capable of other embodiments and of being utilized and carried out in various ways. It is also to be understood that the phrasing and terminology employed herein are for the purpose of description and should not be regarded as limiting.

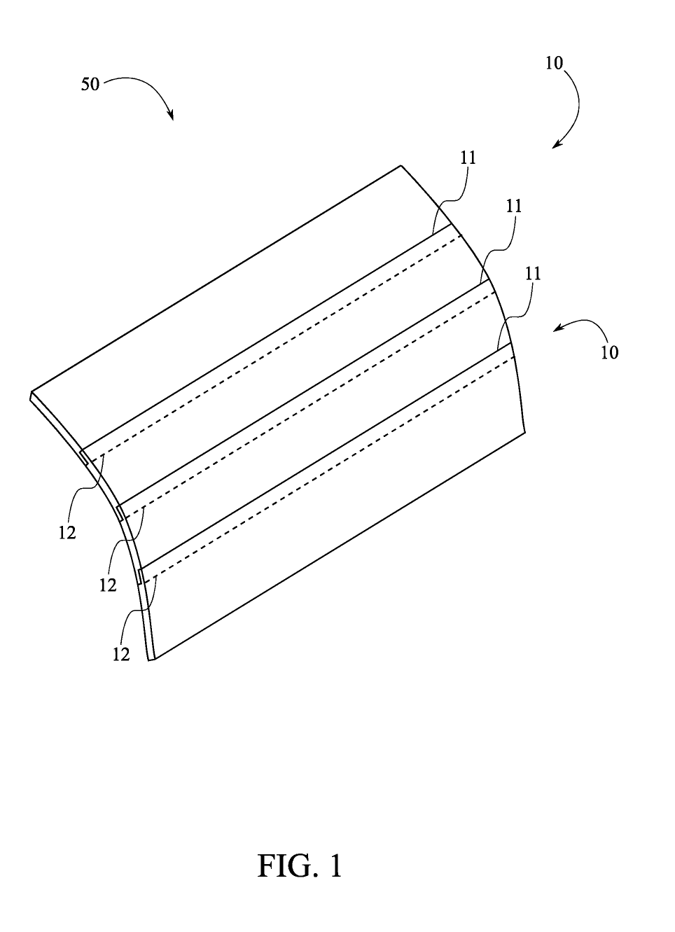

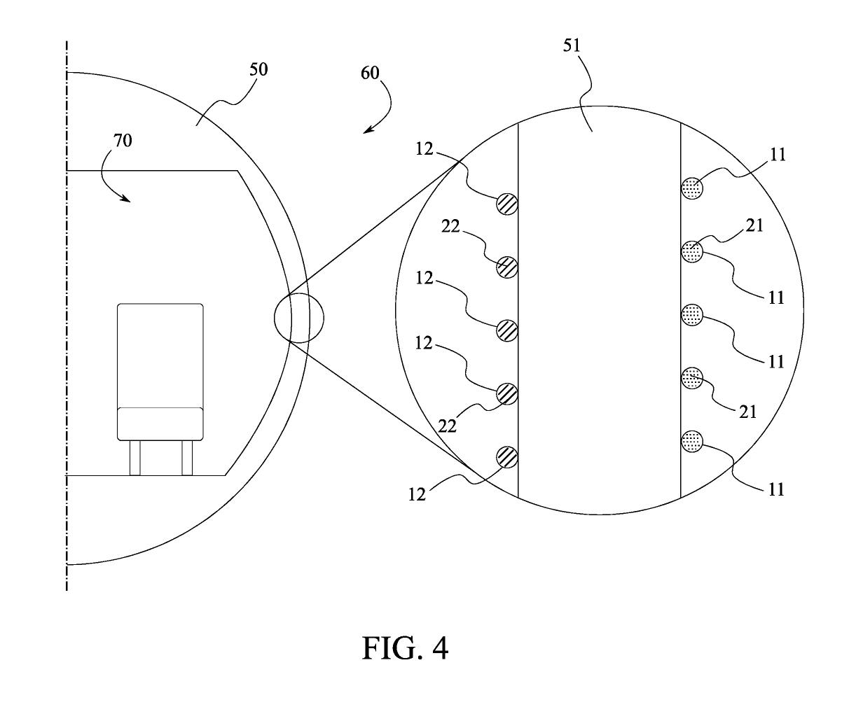

In reference to FIG. 1, the thermopile generator is integrated into an aircraft frame 50 and is formed, at least in part, by a plurality of thermocouple wires 10, wherein the plurality of thermocouple wires 10 is disposed about the aircraft frame 50 in order to form a thermopile circuit 20. In the preferred embodiment of the present invention, the plurality of thermocouple wires 10 comprises a first thermoelectric material 21, a second thermoelectric material 22, a plurality of cold exposed wires 11, and a plurality of heat exposed wires 12. Each of the plurality of cold exposed wires 11 is composed of the first thermoelectric material 21, while each of the plurality of heat exposed wires 12 is composed of the second thermoelectric material 22, as depicted in FIG. 4.

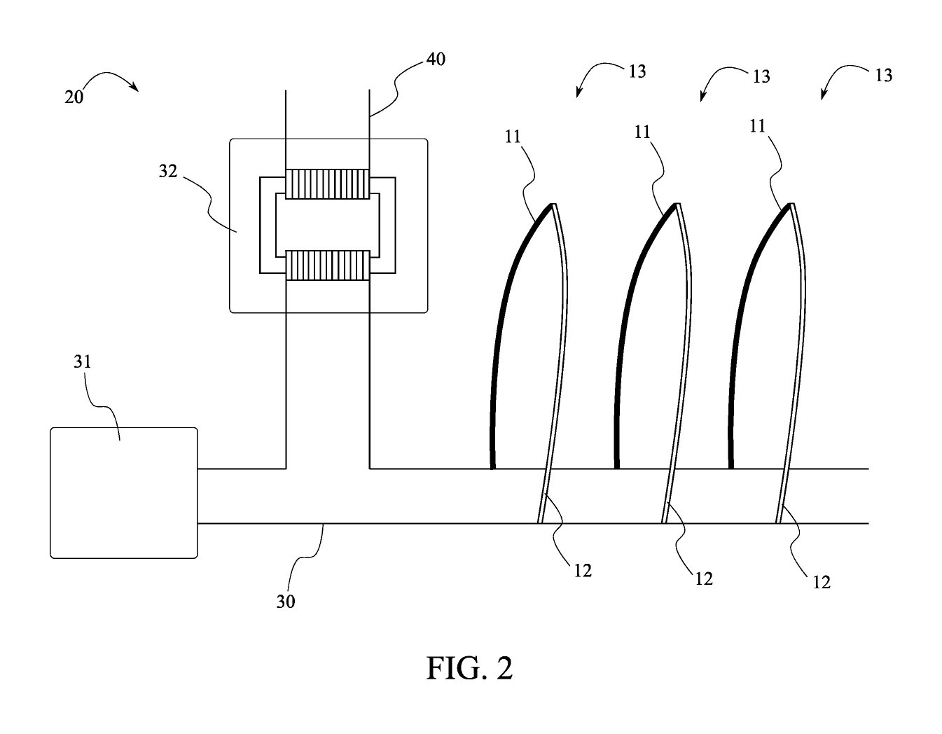

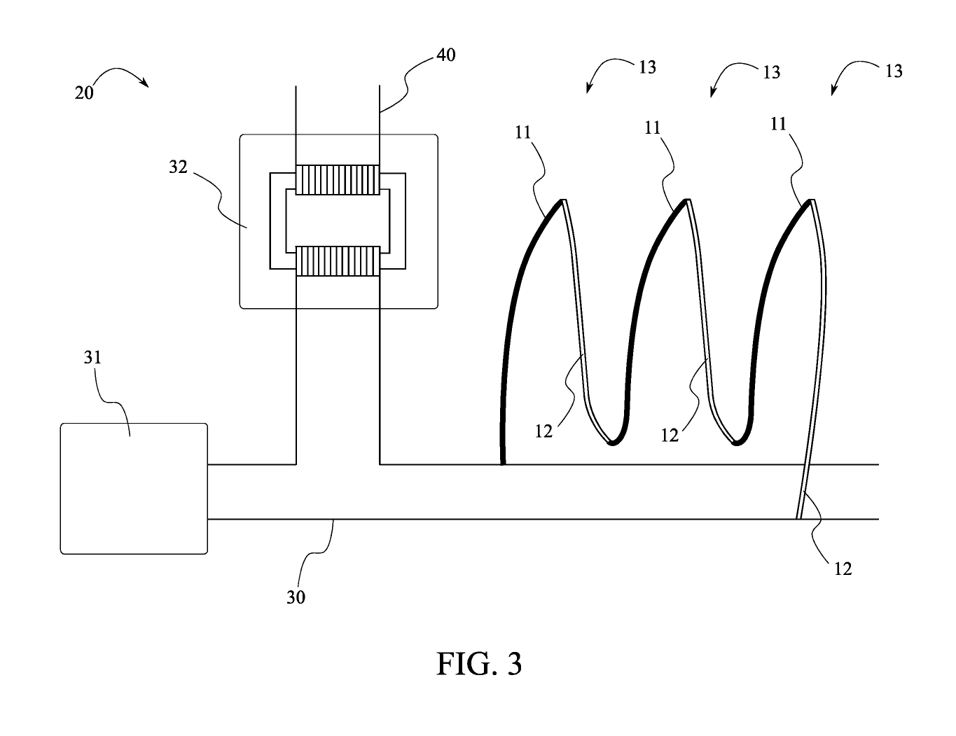

The thermopile circuit 20 is formed in combination by the first thermoelectric material 21 and the second thermoelectric material 22, wherein the plurality of cold exposed wires 11 and the plurality of heat exposed wires 12 are arranged into a plurality of thermocouples 13 disposed about the aircraft frame 50. For each of the plurality of thermocouples 13, a selected wire from the plurality of cold exposed wires 11 is electrically connected to a corresponding wire from the plurality of heat exposed wires 12. In reference to FIG. 2-3, the plurality of thermocouples 13 can be arranged in parallel, in series, or in combination thereof to form the thermopile circuit 20 that is used to produce an electrical current.

When the aircraft is in flight at a cruising altitude, a temperature difference occurs between the interior of the aircraft frame 50 and the exterior of the aircraft frame 50. Thus, there exists a cold side 60 and a hot side 70; the cold side 60 being exteriorly disposed about the aircraft frame 50 and the hot side 70 being interiorly disposed about the aircraft frame 50, as depicted in FIG. 4-6. In reference to FIG. 4, to form the thermopile circuit 20, the plurality of cold exposed wires 11 is positioned about the aircraft frame 50 adjacent to the cold side 60, while the plurality of heat exposed wires 12 is positioned about the aircraft frame 50 adjacent to the hot side 70.

The first thermoelectric material 21, being the plurality of cold exposed wires 11, is electrically connected to the second thermoelectric material 22, being the plurality of heat exposed wires 12. Both the first thermoelectric material 21 and the second thermoelectric material 22 are electrically connected to a step transformer 32 that is electrically connected to an aircraft electrical system 40. When at the cruising altitude, the temperature difference causes the electrical current to be formed in the first thermoelectric material 21 and the second thermoelectric material 22. The electrical current is then directed through the step transformer 32, to the aircraft electrical system 40, wherein the electrical current can be used to power selected devices.

In reference to FIG. 2-3, the plurality of thermocouples 13 is electrically connected to a transfer cable 30 that is used to transfer the electrical current from the plurality of thermocouples 13 to the step transformer 32. One or more diodes may be utilized in conjunction with the plurality of thermocouple wires 10, wherein the diodes direct the electrical current to the transfer cable 30. The specific number of diodes may vary depending on the arrangement of the plurality of thermocouples 13 (i.e. arranged in parallel, in series, or in combination thereof) and the specific number of the plurality of thermocouples 13.

A battery 31 may also be utilized to store energy produced from the thermopile circuit 20. In such a case, the battery 31 is electrically connected to the transfer cable 30, in between the plurality of thermocouple wires 10 and the step transformer 32. In this way, the electrical energy produced from the thermopile circuit 20 can be harnessed, stored, and discretionarily utilized.

The step transformer 32 sends electrical energy directly from the thermopile circuit 20 to the aircraft electrical system 40, or from the battery 31 to the aircraft electrical system 40. Additionally, the step transformer 32 can be used to increase or decrease the voltage of the electrical current. The aircraft electrical system 40 may include, but is not limited to, outlets to power passenger electronics, entertainment systems, or aircraft control systems. The electrical current generated from the thermopile circuit 20 does not need to solely power the aircraft electrical system 40. Rather, the electrical current may simply be used as a supplemental power source.

Through proper calculations and design, weight will be reduced as the specific number of the plurality of thermocouples 13 is determined, as well as the thickness (radius) and length of the plurality of thermocouple wires 10, and the material choice for the first thermoelectric material 21 and the second thermoelectric material 22. As such, the required voltage needed to be generated is to be maximized, while reducing the amount of weight from the plurality of thermocouples 13. Equations that may be used for weight calculations are as follows:

$$\begin{matrix}weight = 2 ρ nl π {r}^{2} & ( 1 ) \\ n = \frac{( required voltage )}{( voltage generated by thermocouple per degree ) ( {T}_{H} - {T}_{C} )} & ( 2 )\end{matrix}$$

Where for equation (1): n=the number of thermocouples; l=the length of each thermocouple; r=the radius of each thermocouple; and p=the density of each thermocouple. And where for equation (2): n=the number of thermocouples; T_{H}=the temperature of the hot side 70; and T_{C}=the temperature of the cold side 60. Actual weight calculations could be obtained by first using equation (1) separately for the first thermoelectric material 21 and the second thermoelectric material 22, and then adding the results.

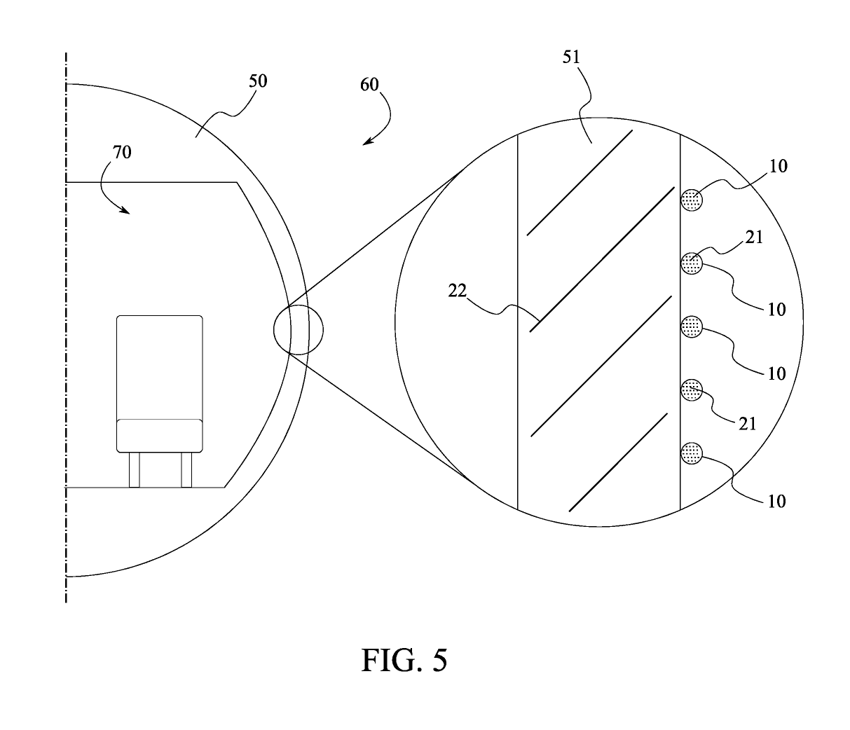

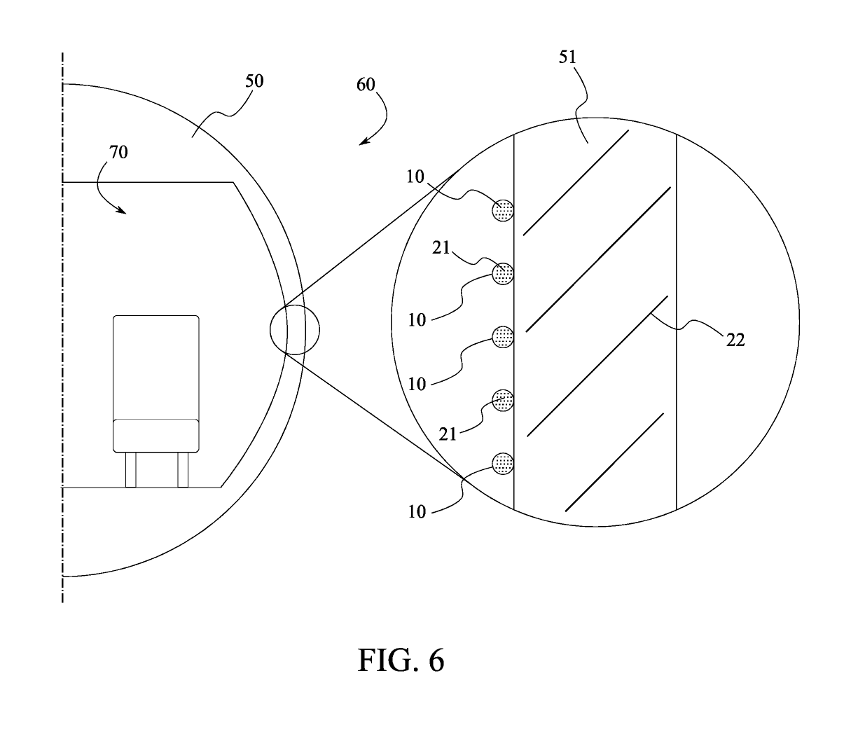

In an alternative embodiment of the present invention, to save more weight, a girder 51 of the aircraft frame 50, which is typically made from aluminum, is used as one of the thermoelectric generator base metals. More specifically, the plurality of thermocouple wires 10 is composed of the first thermoelectric material 21, while the girder 51 is composed of the second thermoelectric material 22, as depicted in FIG. 5-6. This allows for much more savings in weight and uniform distribution of the weight of the thermoelectric generator along the entire length of the aircraft.

The plurality of thermocouple wires 10 is disposed about the aircraft frame 50 to form the thermopile circuit 20 in conjunction with the girder 51. The plurality of thermocouple wires 10 can be disposed about the girder 51, adjacent to the cold side 60, as depicted in FIG. 5, or adjacent to the hot side 70, as depicted in FIG. 6, depending on the chosen material for the first thermoelectric material 21. A lead is electrically connected in between the girder 51 and the transfer cable 30 to complete the thermopile circuit 20.

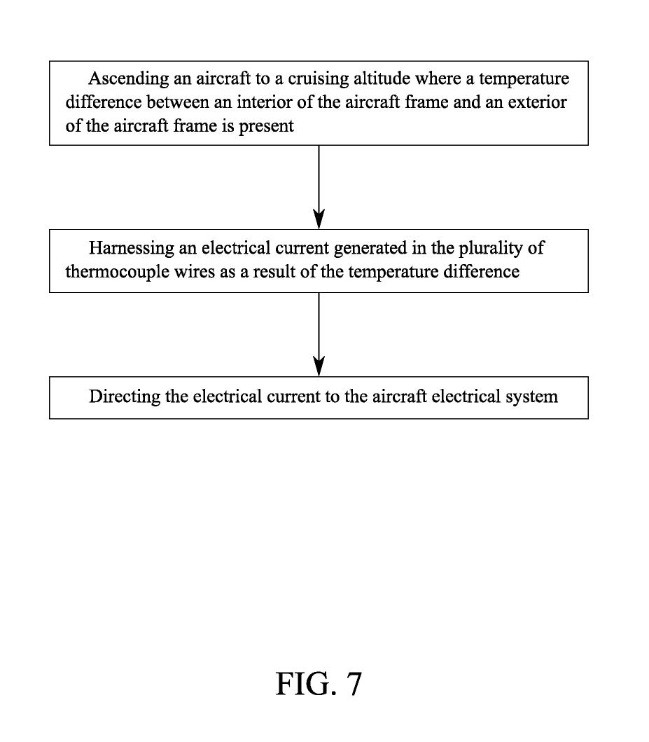

In reference to FIG. 7, in order to provide electricity for the aircraft, the aircraft is first ascended to the cruising altitude where the temperature difference between the interior of the aircraft frame 50 and the exterior of the aircraft frame 50 is present. In general, the exterior of the aircraft frame 50, or the cold side 60, is approximately −45° C., whereas the interior of the aircraft frame 50, or the hot side 70, is approximately 20° C. The temperature difference at the cruising altitude causes the electrical current to be generated in the plurality of thermocouple wires 10, wherein the electrical current is harnessed by the transfer cable 30. The electrical current can then be directed to the aircraft electrical system 40 or to the battery 31.

In other embodiments of the present invention, the thermoelectric generator will be used in conjunction with homes or buildings in warmer countries such as Kuwait, Qatar, and Oman, or other countries. However, saving in weight of the thermoelectric generator is less important in these cases, than as with the present invention as described in the preferred embodiment. In warmer countries, it is common for the outside temperature to be about 45 to 55° C., while the inside of the homes are about 22° C. With this, the thermoelectric generator will generate a voltage due to the temperature difference between the warm side and cold side of the building due to the Seebeck effect.

Although the invention has been explained in relation to its preferred embodiment, it is to be understood that many other possible modifications and variations can be made without departing from the spirit and scope of the invention as hereinafter claimed.

What is claimed is:

1. An airframe having an integrated thermoelectric generator comprises:
an aircraft frame;
a plurality of thermocouple wires;
the plurality of thermocouple wires comprising a first thermoelectric material;
the plurality of thermocouple wires being operably disposed about the aircraft frame in order to form a thermopile circuit;
the first thermoelectric material being electrically connected to a second thermoelectric material;
the thermopile circuit being formed in combination by the first thermoelectric material and the second thermoelectric material; and
the first thermoelectric material and the second thermoelectric material being electrically connected to a step transformer, wherein the step transformer is electrically connected to an aircraft electrical system.

2. An airframe having an integrated thermoelectric generator as claimed in claim 1, wherein the plurality of thermocouple wires comprises the second thermoelectric material.

3. An airframe having an integrated thermoelectric generator as claimed in claim 1 comprises:
the plurality of thermocouple wires comprising a plurality of cold exposed wires and a plurality of heat exposed wires;
the plurality of cold exposed wires being composed of the first thermoelectric material; and
the plurality of heat exposed wires being composed of the second thermoelectric material.

4. An airframe having an integrated thermoelectric generator as claimed in claim 3 comprises:
the plurality of cold exposed wires and the plurality of heat exposed wires being arranged into a plurality of thermocouples, wherein for each of the plurality of thermocouples a selected wire from the plurality of cold exposed wires is electrically connected to a corresponding wire from the plurality of heat exposed wires.

5. An airframe having an integrated thermoelectric generator as claimed in claim 4 comprises:
the plurality of thermocouples being arranged in parallel.

6. An airframe having an integrated thermoelectric generator as claimed in claim 4 comprises:
the plurality of thermocouples being arranged in series.

7. An airframe having an integrated thermoelectric generator as claimed in claim 3 comprises:
a cold side being exteriorly disposed about the aircraft frame; and
the plurality of cold exposed wires being positioned adjacent to the cold side.

8. An airframe having an integrated thermoelectric generator as claimed in claim 3 comprises:
a hot side being interiorly disposed about the aircraft frame; and
the plurality of heat exposed wires being positioned adjacent to the hot side.

9. An airframe having an integrated thermoelectric generator as claimed in claim 1 comprises:
the aircraft frame comprising a girder; and
the girder being composed of the second thermoelectric material.

10. An airframe having an integrated thermoelectric generator as claimed in claim 9 comprises:
a cold side being exteriorly disposed about the aircraft frame; and
the plurality of thermocouple wires being disposed about the girder, adjacent to the cold side.

11. An airframe having an integrated thermoelectric generator as claimed in claim 9 comprises:
a hot side being interiorly disposed about the aircraft frame; and
the plurality of thermocouple wires being disposed about the girder, adjacent to the hot side.

12. A method for providing electricity in an aircraft using an airframe having an integrated thermoelectric generator as claimed in claim 1, the method comprises the steps of:
ascending an aircraft to a cruising altitude where a temperature difference between an interior of the aircraft frame and an exterior of the aircraft frame is present;
harnessing an electrical current generated in the plurality of thermocouple wires as a result of the temperature difference; and
directing the electrical current to the aircraft electrical system.
